(19) United States
(12) Patent Application Publication
(10) Pub. No.: US 2025/0349606 A1
(43) Pub. Date: Nov. 13, 2025

(54) MIXED-SPECIES BUFFER FILM FOR STRUCTURAL INTEGRITY OF METALLIZATION

(71) Applicant: Tokyo Electron Limited, Tokyo (JP)

(72) Inventors: Jack ROGERS, Albany, NY (US); Tek Po Rinus LEE, Albany, NY (US); Kenichi IMAKITA, Albany, NY (US)

(73) Assignee: Tokyo Electron Limited, Tokyo (JP)

(21) Appl. No.: 18/661,470

(22) Filed: May 10, 2024

(51) Int. Cl. H01L 21/768; H01L 23/532

(52) U.S. Cl. CPC H01L 21/76828; H01L 21/76843; H01L 21/76877; H01L 23/53266

(57) ABSTRACT

A method of microfabrication is provided. The method includes providing a wafer including a dielectric layer having an opening formed in the dielectric layer. The opening includes a bottom and a sidewall. A buffer film is formed along the bottom and the sidewall of the opening. A metal material is formed over the buffer film to fill the opening. A first coefficient of thermal expansion (CTE) α₁ of the dielectric layer is larger than a second CTE α₂ of the buffer film, which is larger than a third CTE α₃ of the metal material.

### FIELD OF THE INVENTION

This disclosure relates to microelectronic devices including semiconductor devices, transistors, and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes.

### SUMMARY

The present disclosure relates to a method of microfabrication and a semiconductor device.

According to a first aspect of the disclosure, a method of microfabrication is provided. The method includes providing a wafer including a dielectric layer having an opening formed in the dielectric layer. The opening includes a bottom and a sidewall. A buffer film is formed along the bottom and the sidewall of the opening. A metal material is formed over the buffer film to fill the opening. A first coefficient of thermal expansion (CTE) α₁ of the dielectric layer is larger than a second CTE α₂ of the buffer film, which is larger than a third CTE α₃ of the metal material.

In some embodiments, the buffer film includes a first chemical element corresponding to the metal material and a second chemical element that is different from the first chemical element.

In some embodiments, the buffer film includes a compound including the first chemical element and the second chemical element.

In some embodiments, the metal material includes ruthenium, and the compound includes ruthenium oxide, ruthenium nitride or both.

In some embodiments, the buffer film includes an alloy including the first chemical element and the second chemical element.

In some embodiments, the metal material includes ruthenium, and the second chemical element includes aluminum, cobalt or both.

In some embodiments, a first physical vapor deposition (PVD) process is executed to form the buffer film including ruthenium oxide.

In some embodiments, a chemical vapor deposition (CVD) process is executed to form the metal material including ruthenium.

In some embodiments, a second PVD process is executed to form an initial portion of the metal material that is in contact with the buffer film before executing the CVD process.

In some embodiments, executing the first PVD process includes vaporizing a ruthenium metal source in a PVD chamber and introducing an oxygen gas into the PVD chamber.

In some embodiments, the oxygen gas is introduced into the PVD chamber at a constant flow rate.

In some embodiments, the oxygen gas is introduced into the PVD chamber at a decreasing flow rate.

In some embodiments, at least one of the buffer film or the metal material is at least partially formed by atomic layer deposition (ALD).

In some embodiments, the dielectric layer includes at least one selected from the group consisting of an organosilicate glass, amorphous carbon, porous silicon oxide, a spin-on organic polymeric dielectric, a spin-on silicon-based polymeric dielectric, porous SiOCH, porous poly(arylene ether) and porous methylsilsesquioxane.

In some embodiments, the metal material includes one selected from the group consisting of ruthenium and molybdenum.

In some embodiments, the dielectric layer includes a low-k dielectric having a dielectric constant of 3 or less.

In some embodiments, α₂=xα₁+(1−x)α₃, where x is a number of 0.3-1.

According to a second aspect of the disclosure, a semiconductor device is provided. The semiconductor device includes a conductive layer and a dielectric layer formed over the conductive layer. A metal material is formed in the dielectric layer. A buffer film is formed between the metal material and the dielectric layer. A first coefficient of thermal expansion (CTE) α₁ of the dielectric layer is larger than a second CTE α₂ of the buffer film, which is larger than a third CTE α₃ of the metal material.

In some embodiments, the metal material includes ruthenium, and the buffer film includes ruthenium oxide, ruthenium nitride, a ruthenium-aluminum alloy or a ruthenium-cobalt alloy.

In some embodiments, the buffer film includes ruthenium oxide, and the buffer film has a uniform oxygen concentration or a non-uniform oxygen concentration that decreases from a first side to a second side. The first side faces the dielectric layer. The second side faces the metal material.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a vertical cross-sectional view of a semiconductor device in accordance with one embodiment of the present disclosure.

FIG. 1B shows an expanded view of box 120 in FIG. 1A in accordance with one embodiment of the present disclosure.

FIG. 2 shows a flow chart of a process for manufacturing a semiconductor device, in accordance with some embodiments of the present disclosure.

FIGS. 3, 4, 5, 6, 7, 8 and 9 show vertical cross-sectional views of a semiconductor device at various intermediate steps of manufacturing, in accordance with some embodiments of the present disclosure.

FIG. 10 shows a vertical cross-sectional view of a semiconductor device in conventional technology.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

As semiconductor devices continue to shrink, copper (Cu) metallization has got its own challenges and is becoming more difficult and elusive, especially when the contact critical dimension (CD) is in the sub-30 nm regime. Ruthenium (Ru) metal filling is promising in replacing Cu for contact metallization for example as interconnect metal. However, adhesion of Ru to the underlying or surrounding dielectric material often needs pre-treatment. Moreover, for dual-damascene integration at small pitches, differently sized trenches can result in uneven stress during Ru film deposition, leading to line bending.

As shown in FIG. 10, a semiconductor device 400 can include a substrate 401, an etch stop layer (ESL) 403 over the substrate 401 and a dielectric layer 405 over the ESL 403. A plurality of openings 411 can be formed in the dielectric layer 405 with varying depths. A metal material 407 such as Ru is deposited to fill the openings 411. However, during Ru deposition, line structures 431 of the dielectric layer 405 may bend or deform due to uneven stress of Ru. That is, the line structures 431, which stand perpendicular to the substrate 401 before Ru deposition, will bend to various angles during Ru deposition.

Direct Ru and dielectric contact as illustrated in FIG. 10 can lead to line bending. One traditional solution is to introduce a liner film between Ru and the dielectric. However, such liner-based solutions may induce increased electrical resistance due to the addition of a metal-metal interface.

Techniques herein provide a liner-less Ru deposition process to allow non-Cu metal damascene for superior electrical properties at smaller pitch scaling. A buffer film such as modified Ru can be deposited first which has a coefficient of thermal expansion (CTE) more similar to that of the dielectric, and then Ru deposition can be used to fill the gaps.

According to some aspects of the present disclosure, an Ru alloy (e.g. a ruthenium-aluminum alloy) or a Ru-containing compound (e.g. ruthenium oxide) can be selected which has a coefficient of thermal expansion (CTE) similar to that of a background dielectric (e.g. a low-k dielectric). Therefore, Ru-alloy or RuOx graduated deposition can enable favorable properties including a CTE which closely matches that of the low-k material—a way of mitigating line bending from Ru/dielectric contact during deposition. As a result, an all-in-one package of Ru modification and deposition on a physical vapor deposition (PVD) platform can be enabled which doesn't require a liner. Additionally, Ru deposition herein can be in-situ.

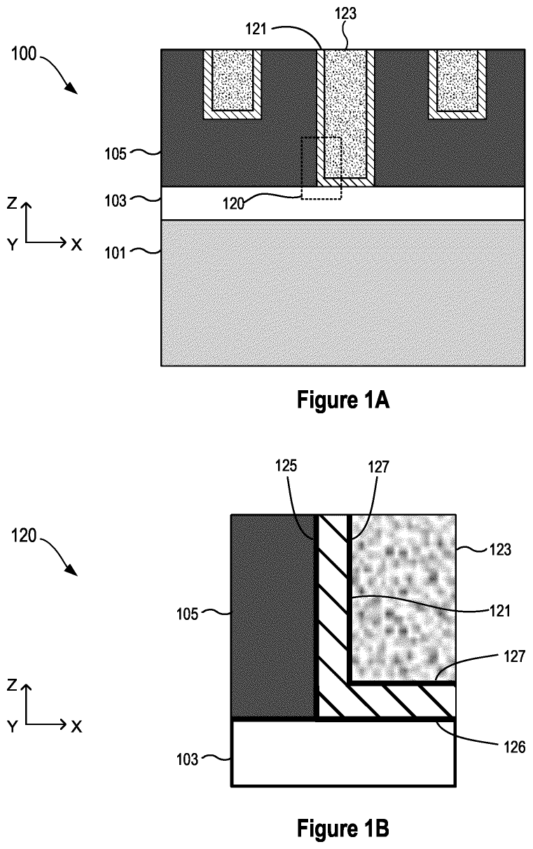

FIG. 1A shows a vertical cross-sectional view of a semiconductor device 100, and FIG. 1B shows an expanded view of box 120 in FIG. 1A in accordance with some embodiments of the present disclosure. As illustrated, the semiconductor device 100 can include a substrate 101, an etch stop layer (ESL) 103 over the substrate 101 and a dielectric layer 105 over the ESL 103. The semiconductor device 100 can also include a metal material 123 formed in the dielectric layer 105. A buffer film 121 is disposed between the metal material 123 and the dielectric layer 105 as well as between the metal material 123 and the ESL 103.

The dielectric layer 105 has a first coefficient of thermal expansion (CTE) α₁. The buffer film 121 has a second CTE α₂. The metal material 123 has a third CTE α₃. Typically, α₁ is larger than α₂ that is larger than α₃. It should be understood that α₁, α₂ and α₃ are not particularly limited to specific values or ranges, but instead can depend on specific material combinations of the dielectric layer 105 and the metal material 123 (and sometimes the buffer film 121 as well), which will be explained in detail later. For instance, α₂ can be designed to have a value of xα₁+ (1−x)α₃, where x is a number of 0 to 1, e.g. 0, 0.1, 0.2, 0.3, 0.4 0.5, 0.6, 0.7, 0.8, 0.9 and 1. x is preferably 0.3-1, preferably 0.5-0.9, preferably 0.6-0.8. That is to say, α₂ is preferably closer to α₁ than to α₃.

In a non-limiting example, the metal material 123 is ruthenium (Ru). The buffer film 121 is ruthenium oxide (RuOₓ). The dielectric layer 105 is SiOCH which incorporates one or more alkyl groups into a silicon-oxide-based material and is also known as an organosilicate glass (OSG) or a carbon-doped oxide (CDO). Accordingly, Ru can have a CTE of 5.1×10⁻⁶/k to 9.6×10⁻⁶/k, e.g. about 6.78×10⁻⁶/k. SiOCH can have a CTE of about 12×10⁻⁶/k. The buffer film 121 containing ruthenium oxide (RuOₓ) can thus have a CTE between 6.78×10⁻⁶/k and 12×10⁻⁶/k, e.g. 7×10⁻⁶/k, 8×10⁻⁶/k, 9×10⁻⁶/k, 10×10⁻⁶/k, 11×10⁻⁶/k, 11.5×10⁻⁶/k or any values therebetween. In addition, a ruthenium-aluminum alloy can have a CTE of 5.5×10⁻⁶/k and 11×10⁻⁶/k and thus can also be used as the buffer film 121.

In one embodiment, the buffer film 121 has a uniform oxygen concentration and thus a uniform CTE. In another embodiment, the buffer film 121 has a non-uniform oxygen concentration and thus a non-uniform CTE, in which case the aforementioned second CTE α₂ can be an average value of the non-uniform CTE. For instance, the non-uniform oxygen concentration can decrease from a first side 125 to a second side 127, linearly or non-linearly. The first side 125 faces the dielectric layer 105 while the second side 127 faces the metal material 123. Accordingly, the non-uniform CTE can decrease from the first side 125 to the second side 127, linearly or non-linearly. Particularly, the non-uniform oxygen concentration can decrease to about zero on the second side 127. Similarly, the non-uniform oxygen concentration and the non-uniform CTE can decrease from a third side 126 to the second side 127, linearly or non-linearly. The third side 126 faces the ESL 103.

In some embodiments, the metal material 123 can include, but is not limited to, ruthenium, molybdenum, tungsten, titanium, niobium, tantalum, aluminum, nickel, chromium, gold, silver, platinum or any combinations thereof. Preferably, the metal material 123 can include ruthenium, molybdenum, tungsten, titanium, tantalum, nickel, chromium, or any combinations thereof. Preferably, the metal material 123 can include ruthenium or molybdenum. Preferably, the metal material 123 includes a single metal of ruthenium. Additionally, the metal material 123 may not include copper.

In some embodiments, the buffer film 121 can include a first chemical element corresponding to the metal material of the metal material 123 and a second chemical element that is different from the first chemical element. For instance, the buffer film 121 can include a compound or alloy including the first chemical element and the second chemical element. Particularly when the metal material 123 includes ruthenium, the buffer film 121 can include, but is not limited to, a ruthenium-based compound such as ruthenium oxide, ruthenium nitride and the like, a ruthenium-based alloy such as a ruthenium-aluminum alloy (also noted as RuAl and known as ruthenium aluminide), a ruthenium-cobalt alloy and the like, or any combinations thereof. The compound or alloy may contain one or more additional chemical elements, especially for the alloy. For instance, boron, platinum, niobium and/or the like can be added to a ruthenium-based alloy to form a ternary alloy, a quaternary alloy and the like. Preferably, the buffer film 121 can include ruthenium oxide, ruthenium nitride, a ruthenium-aluminum alloy or a ruthenium-cobalt alloy. Preferably, the buffer film 121 can include ruthenium oxide or a ruthenium-aluminum alloy. Preferably, the buffer film 121 includes ruthenium oxide.

In some embodiments, the dielectric layer 105 can include one or more dielectric materials. The dielectric layer 105 can include, but is not limited to, a low-k dielectric having a dielectric constant of 3.0 or less, e.g. 3.0, 2.7, 2.5, 2.3, 2.0, 1.8, 1.5, 1.3, 1.1 or any values therebetween. The low-k dielectric can include, but is not limited to, SiOCH, amorphous carbon, porous silicon oxide, a spin-on organic polymeric dielectric (e.g. polyimide, poly(arylene ether), polytetrafluoroethylene, polynorbornenes, benzocyclobutene and the like), a spin-on silicon-based polymeric dielectric (e.g. hydrogen silsesquioxane, methylsilsesquioxane and the like), porous SiOCH, porous poly(arylene ether), porous methylsilsesquioxane, or any combinations thereof. When not described with “porous”, a material is in a dense state or a regular state, as a skilled artisan would understand. Preferably, the dielectric layer 105 can include SiOCH, amorphous carbon, porous silicon oxide, porous SiOCH or any combinations thereof. Preferably, the dielectric layer 105 includes SiOCH which may have a dielectric constant of 2.0-2.8.

In some embodiments, the ESL 103 can include one or more dielectric materials that are configured to be etch-selective to the dielectric layer 105. The ESL 103 can include a low-k dielectric and/or a high-k dielectric. The ESL 103 can include, but is not limited to, silicon oxide, silicon nitride, silicon oxynitride, silicon carbonitride, silicon carbon oxynitride, aluminum oxide, titanium oxide, titanium nitride, hafnium oxide, hafnium silicon oxynitride, tantalum pentoxide, zirconium dioxide, boron carbide, boron nitride, hafnium silicate, zirconium silicate, SiOCH, amorphous carbon, a spin-on organic polymeric dielectric, a spin-on silicon-based polymeric dielectric or any combinations thereof. Preferably, the ESL 103 can include silicon oxide, silicon nitride, silicon oxynitride, silicon carbonitride, silicon carbon oxynitride or any combinations thereof. Note that while examples of the dielectric layer 105 and the ESL 103 may overlap, it should be understood that the dielectric layer 105 and the ESL 103 include different materials in order to be etch-selective to each other. For instance, the dielectric layer 105 and the ESL 103 may respectively include silicon nitride and SiOCH.

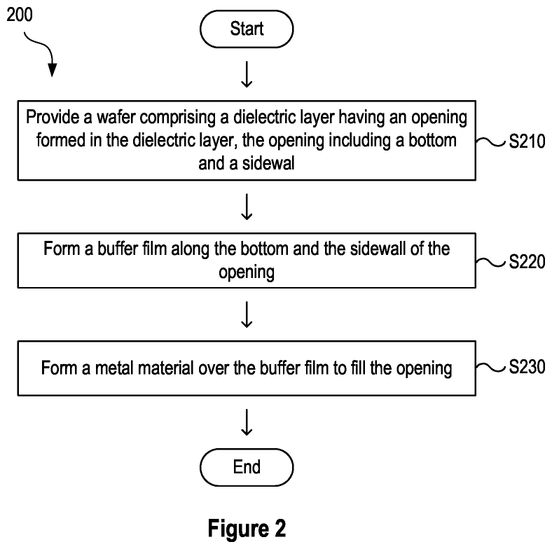

FIG. 2 shows a flow chart of a process 200 for manufacturing a semiconductor device, such as the semiconductor device 100 and the like, in accordance with some embodiments of the present disclosure. At step S210, a wafer is provided which includes a dielectric layer having an opening formed in the dielectric layer. The opening includes a bottom and a sidewall. At step S220, a buffer film is formed along the bottom and the sidewall of the opening. At step S230, a metal material is formed over the buffer film to fill the opening. A first coefficient of thermal expansion (CTE) α₁ of the dielectric layer can be larger than a second CTE α₂ of the buffer film, which may be larger than a third CTE α₃ of the metal material.

FIGS. 3, 4, 5, 6, 7, 8 and 9 show vertical cross-sectional views of a semiconductor device 300 at various intermediate steps of manufacturing, in accordance with some embodiments of the present disclosure. The embodiments of the semiconductor device 300 are similar to the embodiments of the semiconductor device 100 in FIGS. 1A and 1B. Note that similar or identical components are labeled with similar or identical numerals unless specified otherwise. Descriptions have been provided above and will be omitted for simplicity purposes.

As shown in FIG. 3, the semiconductor device 300 can include the substrate 101, the ESL 103 formed over the substrate 101 and the dielectric layer 105 formed over the ESL 103. A hard mask layer 131 can be formed over the dielectric layer 105 and patterned to have an opening 133, for example by lithography.

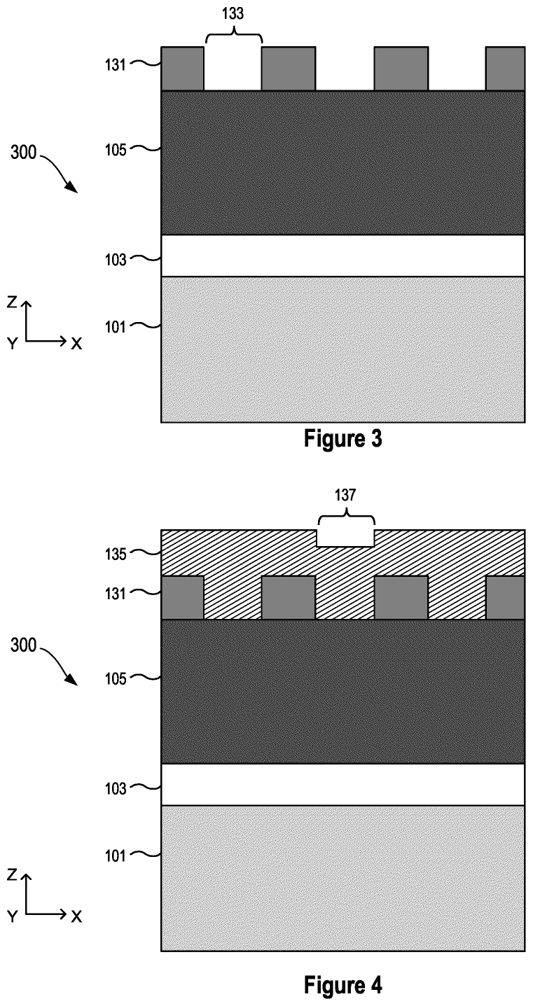

In FIG. 4, a lithography stack 135 (or a lithography layer) can be formed over the hard mask layer 131 and patterned to have an opening 137.

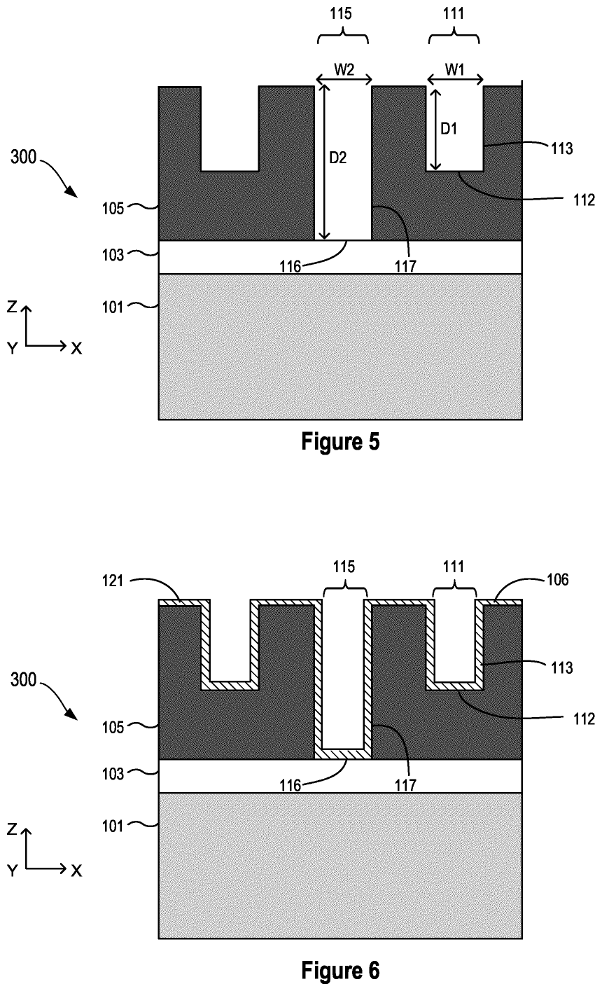

In FIG. 5, the dielectric layer 105 is etched to form a first opening 111 and a second opening 115, and the hard mask layer 131 and the lithography stack 135 are removed. As a result, the opening 133 and the opening 137 are respectively transferred from the hard mask layer 131 and the lithography stack 135 to the dielectric layer 105. The first opening 111 has a first bottom 112 and a first sidewall 113. The second opening 115 has a second bottom 116 and a second sidewall 117. The second opening 115 exposes the ESL 103 while the first opening 111 does not.

The first opening 111 and the second opening 115 may each independently have any shape such as a trench, a slit, a hole, a via, etc. A cross section of the first opening 111 and a cross section of the second opening 115 in the XY plane can each independently have any shape such as a rectangle, a circle, a hexagon, an ellipse or any irregular shape.

The first opening 111 can have a first lateral dimension W1 of 3-20 nm, e.g. 3 nm, 5 nm, 7.5 nm, 10 nm, 12.5 nm, 15 nm, 17.5 nm, 20 nm or any values therebetween. The first opening 111 can have a first depth D1 of 10-90 nm, e.g. 10 nm, 20 nm, 30 nm, 40 nm, 50 nm, 60 nm, 70 nm, 80 nm, 90 nm or any values therebetween. The first opening 111 can have a first aspect ratio, which is defined as D1/W1, of 2-20, e.g. 2, 5, 10, 15, 20 or any values therebetween. Similarly, the second opening 115 can have a second lateral dimension W2 of 3-20 nm, e.g. 3 nm, 5 nm, 7.5 nm, 10 nm, 12.5 nm, 15 nm, 17.5 nm, 20 nm or any values therebetween. The second opening 115 can have a second depth D2 of 10-90 nm, e.g. 10 nm, 20 nm, 30 nm, 40 nm, 50 nm, 60 nm, 70 nm, 80 nm, 90 nm or any values therebetween. The second opening 115 can have a second aspect ratio, which is defined as D2/W2, of 2-20, e.g. 2, 5, 10, 15, 20 or any values therebetween. Nota that D2 is larger than D1. Additionally, various dimensions and ratios (e.g. W1, D1, D1/W1, W2, D2, D2/W2) mentioned herein are merely for illustrative purposes and are not limiting, as a person having ordinary skill in the art would understand.

In FIG. 6, the buffer film 121 can be formed over exposed surfaces including the first bottom 112 and the first sidewall 113 of the first opening 111, the second bottom 116 and the second sidewall 117 of the second opening 115, and a top surface 106 of the dielectric layer 105. The buffer film 121 can have a thickness of a few atomic layers to a few nanometers, e.g. 0.5 nm, 1 nm, 3 nm, 5 nm, 7 nm, 9 nm or any values therebetween.

In a non-limiting example, the dielectric layer 105 includes SiOCH, and the buffer film 121 includes ruthenium oxide. Accordingly, a first physical vapor deposition (PVD) process can be executed to form the buffer film 121 including ruthenium oxide. For instance, a ruthenium metal source can be vaporized or sputtered in a PVD chamber, and an oxygen gas introduced into the PVD chamber. In one embodiment, the oxygen gas is introduced into the PVD chamber at a constant flow rate. Therefore, the buffer film 121 can have a uniform oxygen concentration and a uniform CTE as discussed earlier. In another embodiment, the oxygen gas is introduced into the PVD chamber at a varying flow rate such as a decreasing flow rate. Therefore, the buffer film 121 can have a non-uniform oxygen concentration and a non-uniform CTE as discussed earlier. For illustrative purposes, the buffer film 121 is shown to be conformal. However, it should be understood that the first PVD process may result in a non-conformal film, for example with less material deposition at the first bottom 112 and the second bottom 116 relative to the top surface 106.

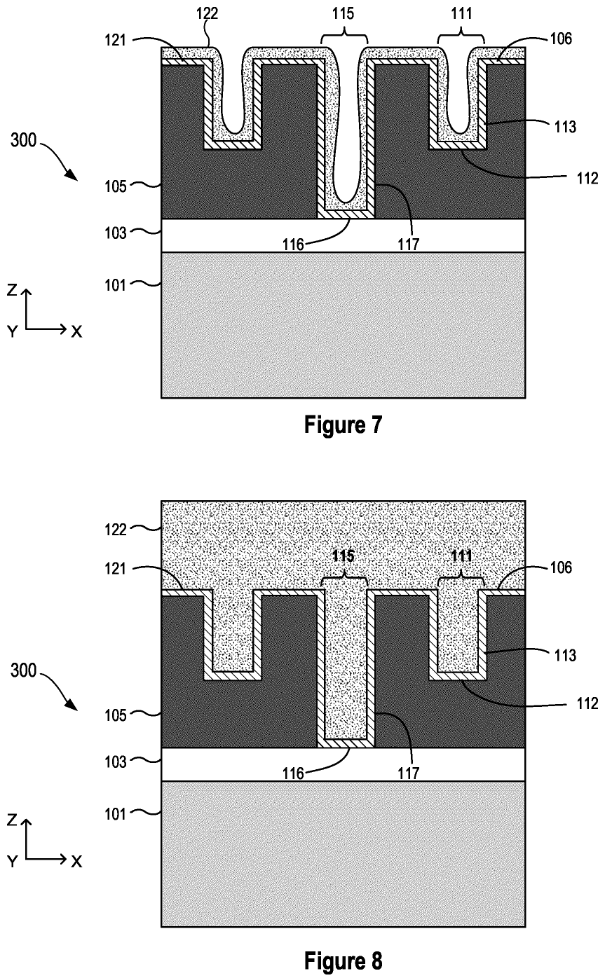

In FIG. 7, a second PVD process can be executed to form an initial portion of a metal material 122 over the buffer film 121. As shown, the initial portion of the metal material 122 can be non-conformal.

In FIG. 8, a chemical vapor deposition (CVD) process can be executed to further deposit the metal material 122 to fill the first opening 111 and the second opening 115. An excessive portion of the metal material 122 may form an overburden over the top surface 106.

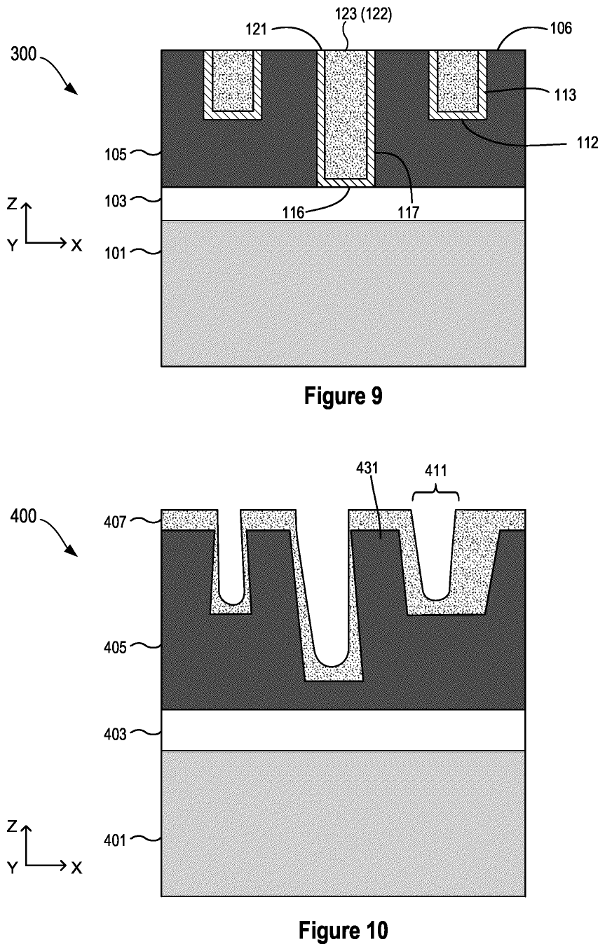

In FIG. 9, the semiconductor device 300 can be etched back or polished down to the top surface 106 or to below the top surface 106. For example, a chemical-mechanical polishing (CMP, also known as chemical-mechanical planarization) process can be executed. The CMP process can stop at the top surface 106 or below the top surface 106. As a result, a remaining portion of the metal material 122 forms the metal material 123. The semiconductor device 300 herein can thus become the semiconductor device 100 in FIGS. 1A and 1B.

As discussed above, FIGS. 3, 4, 5, 6, 7, 8 and 9 can include some embodiments involving the first PVD process, the second PVD process and the CVD process. Note that FIGS. 3, 4, 5, 6, 8 and 9 (without FIG. 7) can show other embodiments involving the first PVD process and the CVD process. That is, the second PVD process in FIG. 7 may not be necessary. The metal material 122 can be formed by the CVD process directly over the buffer film 121 after the first PVD process.

In alternative embodiments, the buffer film 121 and/or the metal material 122 can be at least partially formed by atomic layer deposition (ALD), with or without FIG. 7. In one embodiment, ALD can be utilized in FIG. 6 in lieu of or in addition to the first PVD process to form the buffer film 121 including ruthenium oxide. Accordingly, the buffer film 121 can have a conformal profile as shown in FIG. 6. In another embodiment, ALD can be used in FIG. 7 in lieu of or in addition to the second PVD process to form the initial portion of the metal material 122 of ruthenium. In yet another embodiment, ALD can be used in FIG. 8 in lieu of or in addition to the CVD process.

Particularly in a preferred embodiment, the buffer film 121 is ruthenium oxide, and the metal material 122 is ruthenium. The buffer film 121 can be re-incorporated into a bulk Ru film of the metal material 122 by thermal annealing. For example, the semiconductor device 300 can be thermally annealed after the second PVD process in FIG. 7, after the CVD process in FIG. 8, or after the CMP process in FIG. 9. As a result, the semiconductor device 300 may not have such a distinct RuOx film as represented by the buffer film 121 in FIGS. 7-9. Rather, oxygen atoms can dissipate into the bulk Ru film of the metal material 122. The buffer film 121 and the metal material 122 can thus form a seamless ruthenium layer (or structure) with negligible oxygen impurities, for example negligible as in not affecting electrical properties as demonstrated by Table 1 below which shows stress measurements (e.g. bow values) and sheet resistance (Rs) measurements of some samples in accordance with some embodiments of the present disclosure. Note that in conventional technologies, a buffer film such as a liner or barrier typically maintains its constitution after metal deposition such as a second metal deposition. By contrast, techniques herein offer the stress-control benefit of the liner/barrier during metal deposition while also allowing for the eventual removal of the buffer material. This grants the benefits of the liner film while eliminating any disadvantages of the liner film such as increased resistance.

TABLE 1
Stress and Sheet Resistance Measurements

| | | Bow Before | | | Bow Post | Rs Post |
|---|---|---|---|---|---|---|
| | Sample | Anneal | Rs | Thickness | Anneal | Anneal |
| ID | Description | (μm) | (Ohm/sq) | (nm) | (μm) | (Ohm/sq) |
| 1 | Pre Ru | 63.35 | — | — | — | — |
| 2 | Pre Ru | 69.02 | — | — | — | — |
| 3 | 30 nm Ru | 31.47 | 7.55 | 30.59 ± 0.31 | 79.58 | 4.37 |
| | | (52.5%) | | | | |
| 4 | O-rich 30 nm | 57.11 | 9.15 | 30.85 ± 0.27 | 77.24 | 4.28 |
| | Ru (15 sccm) | (9.85%) | | | | |
| 5 | O-rich 30 nm | 55.74 | 10.81 | 30.68 ± 0.26 | 82.06 | 4.47 |
| | Ru (25 sccm) | (19.2%) | | | | |

In Table 1, Sample 1 and Sample 2 denote two wafers without (or before) buffer film formation and Ru deposition. Sample 1 and Sample 2 respectively have a bow value of 63.35 μm and 69.02 μm, whose average is about 66.19 μm.

Sample 3 denotes a wafer with Ru deposition and without buffer film formation and has a bow value of 31.47 μm. (66.19−31.47)/66.19=52.5%. That is, Sample 3 has a 52.5% change in its bow value after Ru deposition.

Sample 4 denotes a wafer with buffer film formation (e.g. ruthenium oxide) and then Ru deposition. For example, the corresponding buffer film can be formed by the aforementioned first PVD process with a constant oxygen flow rate of 15 sccm (standard cubic centimeter per minute). As a result, Sample 4 has a bow value of 57.11 μm. (63.35−57.11)/63.35=9.85%. That is, Sample 4 has a 9.85% change in its bow value after Ru deposition.

Sample 5 denotes a wafer with buffer film formation (e.g. ruthenium oxide) and then Ru deposition. For example, the corresponding buffer film can be formed by the aforementioned first PVD process with a constant oxygen flow rate of 25 sccm (standard cubic centimeter per minute). As a result, Sample 5 has a bow value of 55.74 μm. (69.02−55.74)/69.02=19.2%. That is, Sample 5 has a 19.2% change in its bow value after Ru deposition.

As can be seen, Sample 3 without buffer film formation has a 52.5% change in its bow value and therefore is prone to line bending as discussed earlier. By contrast, Sample 4 and Sample 5, each with a buffer film of ruthenium oxide, only have a 9.85% change and a 19.2% change in its bow value respectively. Therefore, line bending can be suppressed and even eliminated by the buffer film as stress is reduced between ruthenium oxide and the low-k SiOCH.

While Sample 4 and Sample 5 show slightly larger sheet resistance values than Sample 3 before thermal annealing due to the presence of the buffer film of ruthenium oxide, sheet resistance values of Sample 3, Sample 4 and Sample 5 are close to each other after annealing. That is to say, Rs can be “recovered” by annealing for O-rich deposition, and Ru modification has no lasting impact on electrical performance.

In addition, bow values of Sample 3, Sample 4 and Sample 5 are close to each other after annealing. Note that line bending occurs mostly during Ru deposition, especially at an early stage of Ru deposition before the openings (e.g. 111, 115 and the like) are completely filled with Ru. Accordingly, bow values before annealing can provide better insights into line bending than bow values after annealing.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of microfabrication, the method comprising:
providing a wafer comprising a dielectric layer having an opening formed in the dielectric layer, the opening including a bottom and a sidewall;
forming a buffer film along the bottom and the sidewall of the opening; and
forming a metal material over the buffer film to fill the opening, wherein
a first coefficient of thermal expansion (CTE) α₁ of the dielectric layer is larger than a second CTE α₂ of the buffer film, which is larger than a third CTE α₃ of the metal material.

2. The method of claim 1, wherein:
the buffer film comprises a first chemical element corresponding to the metal material and a second chemical element that is different from the first chemical element.

3. The method of claim 2, wherein:
the buffer film comprises a compound including the first chemical element and the second chemical element.

4. The method of claim 3, wherein:
the metal material includes ruthenium, and
the compound includes ruthenium oxide, ruthenium nitride or both.

5. The method of claim 2, wherein:
the buffer film comprises an alloy including the first chemical element and the second chemical element.

6. The method of claim 5, wherein:
the metal material includes ruthenium, and
the second chemical element includes aluminum, cobalt or both.

7. The method of claim 1, further comprising:
executing a first physical vapor deposition (PVD) process to form the buffer film comprising ruthenium oxide.

8. The method of claim 7, further comprising:
executing a chemical vapor deposition (CVD) process to form the metal material comprising ruthenium.

9. The method of claim 8, further comprising:
executing a second PVD process to form an initial portion of the metal material that is in contact with the buffer film before executing the CVD process.

10. The method of claim 7, wherein executing the first PVD process comprises:
vaporizing a ruthenium metal source in a PVD chamber; and
introducing an oxygen gas into the PVD chamber.

11. The method of claim 10, wherein:
the oxygen gas is introduced into the PVD chamber at a constant flow rate.

12. The method of claim 10, wherein:
the oxygen gas is introduced into the PVD chamber at a decreasing flow rate.

13. The method of claim 1, wherein:
at least one of the buffer film or the metal material is at least partially formed by atomic layer deposition (ALD).

14. The method of claim 1, wherein:
the dielectric layer includes at least one selected from the group consisting of an organosilicate glass, amorphous carbon, porous silicon oxide, a spin-on organic polymeric dielectric, a spin-on silicon-based polymeric dielectric, porous SiOCH, porous poly(arylene ether) and porous methylsilsesquioxane.

15. The method of claim 1, wherein:
the metal material includes one selected from the group consisting of ruthenium and molybdenum.

16. The method of claim 1, wherein:
the dielectric layer comprises a low-k dielectric having a dielectric constant of 3 or less.

17. The method of claim 1, wherein:
α₂=xα₁+ (1−x)α₃, where x is a number of 0.3-1.

18. A semiconductor device, comprising:
a substrate;
a dielectric layer formed over the substrate;
a metal material formed in the dielectric layer; and
a buffer film formed between the metal material and the dielectric layer, wherein
a first coefficient of thermal expansion (CTE) α₁ of the dielectric layer is larger than a second CTE α₂ of the buffer film, which is larger than a third CTE α₃ of the metal material.

19. The semiconductor device of claim 18, wherein:
the metal material comprises ruthenium, and
the buffer film comprises ruthenium oxide, ruthenium nitride, a ruthenium-aluminum alloy or a ruthenium-cobalt alloy.

20. The semiconductor device of claim 19, wherein:
the buffer film comprises ruthenium oxide, and
the buffer film has a uniform oxygen concentration or a non-uniform oxygen concentration that decreases from a first side to a second side, the first side facing the dielectric layer, the second side facing the metal material.
